(19) United States
(12) Patent Application Publication
(10) Pub. No.: US 2010/0314617 A1
(43) Pub. Date: Dec. 16, 2010

(54) VANADIUM DIOXIDE NANOWIRE, FABRICATION PROCESS THEREOF, AND NANOWIRE DEVICE USING VANADIUM DIOXIDE NANOWIRE

(75) Inventor: Daisuke Ito, Kanagawa (JP)

Correspondence Address: SNR DENTON US LLP, P.O. BOX 061080, CHICAGO, IL, 60606-1080, US

(73) Assignee: SONY CORPORATION, Tokyo (JP)

(21) Appl. No.: 12/788,522

(22) Filed: May 27, 2010

(30) Foreign Application Priority Data
Jun. 16, 2009 (JP) 2009-143007

(51) Int. Cl. H01L 29/24; H01L 21/36

(52) U.S. Cl. 257/43; 438/104; 257/E29.1; 257/E21.461

(57) ABSTRACT

A vanadium dioxide nanowire grown long and thin along a [110] direction is disclosed.

### BACKGROUND OF THE INVENTION

1. Field of the Invention

The present invention relates to vanadium dioxide nanowires that show a metal-insulator transition phenomenon, fabrication processes thereof, and nanowire devices that use such vanadium dioxide nanowires.

2. Description of the Related Art

Vanadium dioxide, a monoclinic crystal at room temperature, makes a metal-insulator phase transition to a rutile-type crystal at temperatures in the vicinity of 68° C. (see M. Luo et al., The effect stoichiometry of VO₂ nano-grain ceramics on their thermal and electrical properties, Materials Chemistry and Physics, 104, 258-260 (2007); 3. Results and discussion, FIG. 4; Non-Patent Document 1). It is widely known that the phase transition involves changes in electrical resistance value as large as three orders of magnitude or more. Because of a large temperature dependence of electrical resistance, vanadium dioxide has been used for bolometric infrared temperature sensors (see, for example, JP-A-2007-225532; paragraphs 0036 to 0041, FIG. 1; Patent Document 1).

There have also been reports that a VO₂ thin film undergoes a metal-insulator phase transition under electric field, and thus has potential in applications such as in field-effect transistors, switching devices, memory devices, and electrochromic devices (see, for example, JP-A-2007-224390 (paragraphs 0026 to 0039, 0061 to 0080, FIG. 1, FIG. 11 to FIG. 13; Patent Document 2), JP-T-2006-526273 (paragraphs 0025 to 0028, FIG. 3 to FIG. 5; Patent Document 3), JP-A-2007-515055 (paragraphs 0007 to 0022, FIG. 1, FIG. 2; Patent Document 4), and JP-A-2008-205140 (paragraphs 0023 to 0035, 0049 to 0065, FIG. 1, FIG. 4, FIG. 6 to FIG. 9; Patent Document 5), H-T. Kim, et al., Raman study of electric-field-induced first order metal-insulator transition in VO₂-based, Applied Physics Letters, 86, 242101 (2005) (the right-hand column of 242101-1, the left-hand column of 242101-2, FIG. 1; Non-Patent Document 2), P. JIN and S. Tanemura, Formation and thermochromism of VO₂ Films Deposited by RF Magnetron Sputtering at Low Substrate Temperature, Jpn. J. Appl. Phys. 33 (1994) pp. 1478-1483 (2. Experimental; Non-Patent Document 3), and J. Maeng et al., Fabrication, structural and electrical characterization of VO₂ nanowires, Materials Research Bulletin, 43 (2008) 1649-1656 (2. Experimental, 3.1 Synthesis and structural characterization of VO₂ nanowires, 3.2 Electrical characterization of VO₂ nanowires; Non-Patent Document 6)).

Formation of VO₂ thin films using methods such as a sputtering method and a pulsed laser deposition (PLD) method has been reported (see, for example, Non-Patent Documents 2 and 3, and Patent Documents 2 and 5). However, because the VO₂ thin films described in these publications have a polycrystalline structure, there is non-uniformity in the number of crystal grains per unit area, and in the crystal orientation plane and crystal grain dimensions. It is accordingly difficult to make a uniform phase transition. In single crystalline thin films, an increased amount of energy may be required to make a phase transition throughout the crystal, and sufficiently large external field energy (heat, light, electric field, pressure) is considered necessary, because such thin films are highly crystalline over a large two dimensional area, and thus easily diffuse heat, light, or current within the crystal.

Nanosized, uniform single crystals are necessary to overcome these drawbacks. Particularly, nanowires, with their one-dimensional structure, allow crosslinkage between electrodes, and enable efficient phase transitions because the propagation direction of the external field energy in the crystals is along the direction of extension of the wires.

Techniques to fabricate single crystalline VO₂ nanowire structures are reported (see, for example, B. Guiton et al., Single-Crystalline Vanadium Dioxide Nanowires with Rectangular Cross Sections, J. AM. CHEM. SOC., 2005, 127, 498-499 (line 22 in the left-hand column of page 498 to line 15 in the right-hand column of page 499, FIG. 1, FIG. 2; Non-Patent Document 4), J. Sohn et al., Direct Observation of the Structural Component of the Metal-Insulator Phase Transition and Growth Habits of Epitaxially Grown VO₂ Nanowires, Nano Lett., 7, No. 6 (2007) 1570-1574 (line 15 in the left-hand column of page 1571 to line 45 in the left-hand column of page 1573, FIG. 1, FIG. 2, FIG. 3; Non-Patent Document 5), and Non-Patent Document 6). The fabrication techniques described in these publications are vapor-solid (VS) growth methods in which VO₂ powders are heated.

FIG. 17 shows a SEM image of VO₂ nanowires of related art, taken from (a) in FIG. 1 of Non-Patent Document 4.

The VO₂ nanowires shown in FIG. 17 are formed on a Si₃N₄ substrate with VO₂ powders using a vapor-solid (VS) growth method (also known as a heat vapor deposition method; growth temperature 900° C., growth time 5 h). The growth axis of the VO₂ nanowires is along the [100] direction.

FIG. 18 shows SEM images ((a) and (b)), a TEM image ((c)), and an electron diffraction pattern ((d)) of VO₂ nanowires of related art, taken from FIG. 1 of Non-Patent Document 5.

The VO₂ nanowires shown in FIG. 18 are formed with VO₂ powders on a sapphire c-plane using a vapor-solid (VS) growth method (growth temperature 600 to 700° C., growth time 2 to 5 h), and the VO₂ nanowires have a [100] growth direction. The VO₂ nanowires make a 60° (and/or 120°) angle with each other, or are parallel to each other.

Techniques to form CNTs (carbon nanotubes) and ZnO nanowires using metal nanoparticles or nanodots as growth catalysts have been reported (see, for example, J. H. Hafner et al., Catalytic growth of single-wall carbon nanotubes from metal particles, Chemical Physics Letters, 296 (1998) 195-202 (2. Experimental, 3. Results; Non-Patent Document 7), S W Kim and S. Fujita, ZnO nanowires with high aspect ratios grown by metalorganic chemical vapor deposition using gold nanoparticles, Applied Physics Letters, 86, 153119 (2005) (FIG. 1, FIG. 2; Non-Patent Document 8), and D. Ito et al., Selective Growth of Vertical ZnO Nanowire Arrays Using Chemically Anchored Gold Nanoparticles, ACS Nano 2, 2001 (2008) (FIG. 1, FIG. 4, FIG. 5; Non-Patent Document 9)).

A vapor-liquid-solid (VLS) growth method that uses metal nanodots as growth catalysts is widely known (see, for example, JP-A-2007-319988 (paragraphs 0003 to 0004, 0010 to 0016, FIG. 4; Patent Document 6)). Gate-around transistors using nanowires are also known (see, for example, JP-A-2008-500719 (paragraphs 0037 to 0067, FIG. 1a to FIG. 3d; Patent Document 7)).

### SUMMARY OF THE INVENTION

Non-Patent Documents 4 to 6 describe forming VO₂ nanowires on a substrate with VO₂ powders using a vapor-solid (VS) growth method. As described in these publications, the growth axis of the VO₂ nanowires is along the [100] direction (here and below, [h, k, l] represents a direction vertical to the crystal plane (h, k, l) according to the Miller indices (or plane indices)).

As shown in FIG. 17, the VO₂ nanowires formed on the substrate according to the method of Non-Patent Document 4 are randomly oriented in different directions, and are non-uniform in terms length and width. Similar VO₂ nanowires are described in Non-Patent Document 6.

As shown in FIG. 18, the VO₂ nanowires formed on the substrate according to the method of Non-Patent Document 5 make a 60° (and/or 120°) angle, or a 180° angle with each other. As above, the VO₂ nanowires formed on the substrate are oriented in different directions, and are non-uniform in terms of length and width.

VO₂ undergoes a metal-insulator phase transition at temperatures in the vicinity of 68° C., and its electrical resistance and optical transmittance (or reflectance) have a large temperature dependence. Because of these properties and the catalytic activity similar to those exhibited by common metal oxides, VO₂ has potential application in a variety of fields.

In two-dimensional sensors using VO₂ nanowires, it is desirable that the VO₂ nanowires formed on the substrate be uniformly aligned in the same direction. However, this is not the case in the related art, in which the VO₂ nanowires are randomly scattered over the substrate. Device application of the VO₂ nanowires is difficult to achieve in this state, and is not practical from the standpoint of device fabrication, because the VO₂ nanowires need to be separated once from the substrate, collected, and disposed again to desired, required positions.

When the VO₂ nanowires formed have a wide size distribution over a diameter range of from about 10 nm to about 1 μm, the non-uniform nanowire diameter is expected to cause non-uniform phase transitions. Such random diameters thus present a big obstacle to device development.

From the standpoint of device development, it is desirable to form the VO₂ nanowires on a substrate in a controlled manner with a uniform diameter and length and with the lengthwise direction (the growth direction of the nanowires) being directed in the same direction. However, such control is not considered in any of the related art documents.

In the methods of the related art, control of growth direction is in principle difficult because the VO₂ nanowires are formed in the state of being randomly scattered on the substrate. The random scattering stems from the crystal growth mechanism of the VO₂ crystals that tend to undergo self growth with the most stable structure.

The most stable structure of VO₂ nanowire crystals is that in which the side faces of the nanowires lie on the {110} planes, and in which the crystalline growth direction is the [100] direction. In the most stable structure, control of growth position and growth direction is not possible because the nanowires begin crystalline growth autonomously from the points of initial crystal nucleus formation. Specifically, the nanowires undergo crystalline growth not only in the [100] direction but in the [110] direction along which the nanowires increase diameter, making it practically impossible to control nanowire diameter and length.

As described above, it has not been possible in the related art to form VO₂ nanowires in a controlled region of the substrate while controlling direction, length, and diameter (width direction orthogonal to the lengthwise direction) in substantially a uniform fashion.

By realizing VO₂ nanowires that can be formed in high density in a controlled region of a substrate while controlling direction, length, and diameter in substantially a uniform fashion, it would be possible to use such VO₂ nanowires and realize, for example, devices having reduced degrees of anisotropy in electrical and optical properties, and catalytic devices having large active areas.

As described in Non-Patent Documents 7 to 9, the technique to form CNTs (carbon nanotubes) or ZnO nanowires using metal nanoparticles or nanodots as growth catalysts enables the nanowires to be formed only in places where the catalysts are disposed, and thus provides the same diameter for the catalysts and the nanowires. The technique also enables growth control in the vertical and horizontal directions.

However, because parameters such as the functional catalyst for the nanowire growth, growth conditions of the nanowires, and the substrate material used for the formation of the nanowires differ depending on the material of the nanowires, the techniques described in Non-Patent Documents 7 to 9 cannot be directly applied to common materials. Indeed, formation of VO₂ nanowires using the technique that uses a growth catalyst has not been realized. Further, there have been no reports concerning formation of VO₂ nanowires using a vapor-liquid-solid growth method that uses metal nanodots as growth catalysts.

Accordingly, there is a need for vanadium dioxide nanowires formed in high density on a substrate with controlled nanowire region, direction, and length, fabrication processes thereof, and nanowire devices that use such vanadium dioxide nanowires.

According to an embodiment of the present invention, there is provided a vanadium dioxide nanowire grown long and thin along a [110] direction.

According to another embodiment of the present invention, there is provided a vanadium dioxide nanowire fabrication process that includes a first step of forming a transition-metal-atom growth catalyst on a substrate, and a second step of growing a nanowire of vanadium dioxide on a surface of the substrate heated under reduced pressure in an atmosphere of any one of oxygen gas, inert gas, and a mixed gas of these.

According to yet another embodiment of the present invention, there is provided a nanowire device realized as any one of: an electronic device including the vanadium dioxide nanowire, and that detects changes in electrical resistance in response to heat, electric field, infrared rays, visible light, electromagnetic waves, pressure, or vibration, or changes in the transmittance or reflectance of infrared rays or visible light; an electronic device that includes an electrode realized by the vanadium dioxide nanowire; and a catalytic device in which the vanadium dioxide nanowire is used as a photocatalyst or an alcoholysis catalyst.

According to the embodiments of the present invention, the vanadium dioxide nanowire grown long and thin along the direction can be formed by crystalline growth using a vapor-liquid-solid growth method upon appropriately selecting a substrate material and a crystal plane, and forming metal nanoparticles or metal nanodots as growth catalysts on a substrate surface. The vanadium dioxide nanowire is formed with controlled diameter, growth direction, and length.

According to the embodiments of the present invention, a vanadium dioxide nanowire with controlled diameter, growth direction, and nanowire region can be fabricated by the process that includes a first step of forming a transition-metal-atom growth catalyst on a substrate, and a second step of growing a nanowire of vanadium dioxide on a surface of the substrate heated under reduced pressure in an atmosphere of any one of oxygen gas, inert gas, and a mixed gas of these.

According to the embodiments of the present invention, because vanadium dioxide nanowires of a uniform shape can be formed in high density with controlled diameter, growth direction, length, and nanowire region, the vanadium dioxide nanowires can be used to provide an electronic device that can detect changes in electrical resistance, or changes in the transmittance or reflectance of infrared rays or visible light at high sensitivity, an electronic device having high energy output, an electronic device such as a battery and a capacitor, and a high-performance catalytic device having a large catalyst active area.

### BRIEF DESCRIPTION OF THE DRAWINGS

FIGS. 1A and 1B are cross sectional views explaining growth of VO₂ nanowires according to an embodiment of the present invention.

FIGS. 2A and 2B are perspective views explaining a difference in the growth direction of VO₂ nanowires with and without a catalyst according to an embodiment of the present invention.

FIGS. 3A to 3C are perspective views and atomic arrangement views explaining the crystalline structure and crystalline growth of VO₂ according to an embodiment of the present invention.

FIG. 4 is a diagram explaining a schematic structure of a VO₂ nanowire fabrication apparatus according to an embodiment of the present invention.

FIG. 5 is a perspective view explaining a basic structure of a three-dimensional nanowire device that uses VO₂ nanowires vertically grown on a substrate surface according to an embodiment of the present invention.

FIGS. 6A to 6F are cross sectional views schematically explaining fabrication steps of a field-effect transistor (FET) that uses vertically oriented VO₂ nanowires according to an embodiment of the present invention.

FIGS. 7A and 7B are perspective views explaining a redox capacitor that uses vertically grown VO₂ nanowires according to an embodiment of the present invention.

FIGS. 8A and 8B are perspective views explaining a sensor device that uses VO₂ nanowires according to an embodiment of the present invention.

FIGS. 9A and 9B are perspective views explaining a catalytic device that uses VO₂ nanowires according to an embodiment of the present invention.

FIG. 10 is a graph representing VO₂ nanowire formation in relation to temperature and pressure according to Example of the present invention.

FIG. 11 is a photographic view showing a SEM image of VO₂ nanowires formed on a TiO₂ (100) plane according to Example of the present invention.

FIG. 12 is a photographic view showing (a) a SEM image, (b) a TEM image, and (c) an electron diffraction image concerning the VO₂ nanowires formed on the TiO₂ (100) plane according to Example of the present invention.

FIGS. 13A and 13B are photographic views showing SEM images of VO₂ nanowires formed on a TiO₂ (110) plane according to Example of the present invention.

FIG. 14 is a photographic view showing a SEM image of VO₂ nanowires according to Comparative Example of the present invention.

FIG. 15 is a diagram representing Raman spectroscopy spectra of the VO₂ nanowires according to Comparative Example of the present invention.

FIG. 16 is a diagram representing an X-ray diffraction pattern of the VO₂ nanowires according to Comparative Example of the present invention.

FIG. 17 is a photographic view showing a SEM image of VO₂ nanowires of related art.

FIG. 18 is a photographic view showing a SEM image, a TEM image, and an electron diffraction pattern of VO₂ nanowires of related art.

### DESCRIPTION OF THE PREFERRED EMBODIMENTS

A vanadium dioxide nanowire of an embodiment of the present invention may be configured to have a diameter of 2 nm or more and 1 μm or less. The vanadium dioxide nanowire is grown long and thin along a [110] direction, and cannot be practically obtained by machining or the like from bulk single crystals obtained by crystalline growth.

A vanadium dioxide nanowire fabrication process of an embodiment of the present invention may be configured to grow the nanowire long and thin along a [110] direction. This makes it possible to realize, for example, an electronic device having reduced degrees of anisotropy in electrical properties and optical properties, and a catalytic device having a large active area.

The fabrication process may be configured so that the substrate surface on which the nanowire is grown is a crystal plane having a crystal lattice mismatch rate of 10% or less for the vanadium dioxide. This reduces the misfit between the substrate and the nanowire, and thus provides a sufficient bond strength between the nanowire and the substrate, making it possible to stably form the nanowire on the substrate.

The fabrication process may be configured so that the nanowire grows in a 90° or 45° direction with respect to the substrate surface. In this way, the nanowire can be grown on the substrate in high density.

The fabrication may be configured so that the nanowire grows in a 90° direction with respect to the substrate surface when the substrate is tetragonal TiO₂ and when the crystal plane is (110), and grows in a 45° direction with respect to the substrate surface when the substrate is tetragonal TiO₂ and when the crystal plane is (100). This reduces the misfit between the substrate and the nanowire, and thus provides a sufficient bond strength between the nanowire and the substrate, making it possible to stably form the nanowire on the substrate in high density.

The fabrication process may be configured so that, in a second step, the nanowire is grown under a reduced pressure of 10 Pa or more and 1,000 Pa or less. In this way, the vanadium dioxide nanowire can be formed on the substrate without forming a continuous vanadium dioxide film.

The fabrication process may be configured so that, in the second step, the substrate is heated to 400° C. or more and 1,200° C. or less. In this way, formation of vanadium oxide of compositions other than the vanadium dioxide nanowire can be suppressed.

The fabrication process may be configured so that, in the second step, the substrate is heated to 730° C. or more and 1,200° C. or less, and the nanowire is grown under a reduced pressure of 10 Pa or more and 1,000 Pa or less. In this way, the vanadium dioxide nanowire can be formed on the substrate even more stably.

The fabrication process may be configured so that nanoparticles or nanodots are used as a growth catalyst, and that any one of Au, Pt, Ag, Pd, Ru, Fe, Ni, and Cr is used as the transition metal atom for the growth catalyst. In this way, the metal-insulator phase transition temperature of the vanadium dioxide nanowire can be varied while maintaining the basic properties of the base material vanadium dioxide.

The fabrication process may be configured so that the nanowire is grown using a laser vapor deposition method or a heat vapor deposition method, using at least one of an alloy, an oxide, an organic complex compound each containing vanadium as the base element, and a vanadium metal. In this way, the vanadium dioxide nanowire can be formed at low cost using a widely known, common vapor deposition method.

The fabrication process may be configured so that the diameter of the growth catalyst is controlled to control the diameter of the nanowire. In this way, because the vanadium dioxide nanowire grows bottom-up by the action of the growth catalyst, the diameter of the nanowire can be readily controlled. Further, by using growth catalysts of substantially the same diameter, vanadium dioxide nanowires of substantially the same diameter can be obtained.

The fabrication process may be configured so that the growth catalyst has a diameter of 10 nm or more and 1 μm or less. In this way, a long, thin vanadium dioxide nanowire grown in a [110] direction can be obtained that cannot be practically obtained by machining or the like from bulk single crystals obtained by crystalline growth.

The fabrication process may be configured so that, in a first step, the growth catalyst is formed in a desired region of the substrate using any one of an etching method, shadow-mask vapor deposition, and a lift-off method. In this way, a long, thin vanadium dioxide nanowire grown in a [110] direction can be obtained that cannot be practically obtained by machining or the like from bulk single crystals obtained by crystalline growth.

The fabrication process may be configured to include a third step of removing the growth catalyst at an apical portion of the nanowire. In this way, the nanowire structure will be solely of vanadium dioxide, free from any electrical or optical influence of the growth catalyst.

The fabrication process may be configured so that the nanowire includes at least one of a 3d transition metal element, a rare-earth element, Ta, and W as an addition element. In this way, the metal-insulator phase transition temperature of the vanadium dioxide nanowire can be varied while maintaining the basic properties of the base material vanadium dioxide.

The fabrication process may be configured so that the addition element is contained in a content of 5% (at %, atomic fraction) or less. In this way, the metal-insulator phase transition temperature of the vanadium dioxide nanowire can be varied while maintaining the basic properties of the base material vanadium dioxide. The addition element is added by doping, after the vanadium dioxide nanowire has grown.

A nanowire device of an embodiment of the present invention may be configured so that the electronic device realized by the nanowire device is a temperature-detecting sensor device, an acceleration-detecting sensor device, a gas-detecting sensor device, an electromagnetic wave-detecting sensor device, a photo-detecting sensor device, a pressure-detecting sensor device, a field-effect transistor device, a nonvolatile memory device, a photoelectric conversion device, an optical switching device, a heat modulation device, a light modulation device, a switching circuit device, a phototransistor device, or an optical memory device, and that the electrode of an electronic device realized by the nanowire device is any one of an electrical double layer capacitor electrode, an electrochemical capacitor electrode, and a positive electrode for alkali-ion secondary batteries. In this way, it is possible to provide an electronic device having reduced degrees of anisotropy in electrical properties and optical properties, and that can detect changes in electrical resistance, or changes in the transmittance or reflectance of infrared rays or visible light at high sensitivity. It is also possible to provide an electronic device having high energy output, an electronic device such as a battery and a capacitor, and a high-performance catalytic device having a large catalyst active area.

In an embodiment of the present invention, nanoparticles or nanodots formed of transition metal atoms (for example, Au, Pt, Ag, Pd, Ru, Fe, Ni, and Cr) are formed on a substrate, and vanadium dioxide nanowires are grown under a reduced pressure of 10 Pa or more and 1,000 Pa or less in an atmosphere of any one of oxygen gas, inert gas, and a mixed gas of these on a surface of the substrate heated to 400° C. or more and 1,200° C. or less, using a vapor-liquid-solid (VLS) growth method and the nanoparticles or nanodots as growth catalysts. The vapor-liquid-solid growth is performed by a laser vapor deposition method or a heat vapor deposition method, using at least one of an alloy, an oxide, an organic complex compound each containing, for example, vanadium (V) as the base element, and a vanadium metal.

By controlling the region (position) of the substrate where the nanoparticles or nanodots (growth catalysts) are formed, the vanadium dioxide nanowires can be grown long and thin along the [110] direction with controlled growth direction in a region of desired patterns. The diameter of the vanadium dioxide nanowires can be controlled by the diameter of the nanoparticles or nanodots, and the length of the vanadium dioxide nanowires can be controlled by the crystal growth time of the vapor-liquid-solid growth.

The substrate surface used is preferably a crystal plane that has a crystal lattice mismatch rate of 100 or less for the vanadium dioxide. Particularly, when tetragonal TiO₂ is used as the substrate and the crystal plane for the growth of the vanadium dioxide nanowire is a (110) plane, the vanadium dioxide nanowire can be grown in a 90° direction with respect to the substrate surface. When the crystal plane for the growth of the vanadium dioxide nanowire is a (100) plane, the vanadium dioxide nanowire can be grown in a 45° direction with respect to the substrate surface.

In the embodiment of the present invention, the vanadium dioxide nanowire is formed on a substrate surface in such a manner that its longitudinal direction crosses the substrate surface with an angle of, for example, 45° or 90°. This is completely different from the related art in which the longitudinal direction of the vanadium dioxide nanowire formed on a substrate surface is parallel to the substrate surface. In this manner, the present invention enables formation of vanadium dioxide nanowires on a substrate in high density.

Thus, the present invention enables high-density formation of vanadium dioxide nanowires on a substrate with controlled nanowire region (nanowire position) and controlled diameter, growth direction, and length.

Embodiments of the present invention will now be described in detail below with reference to the accompanying drawings.

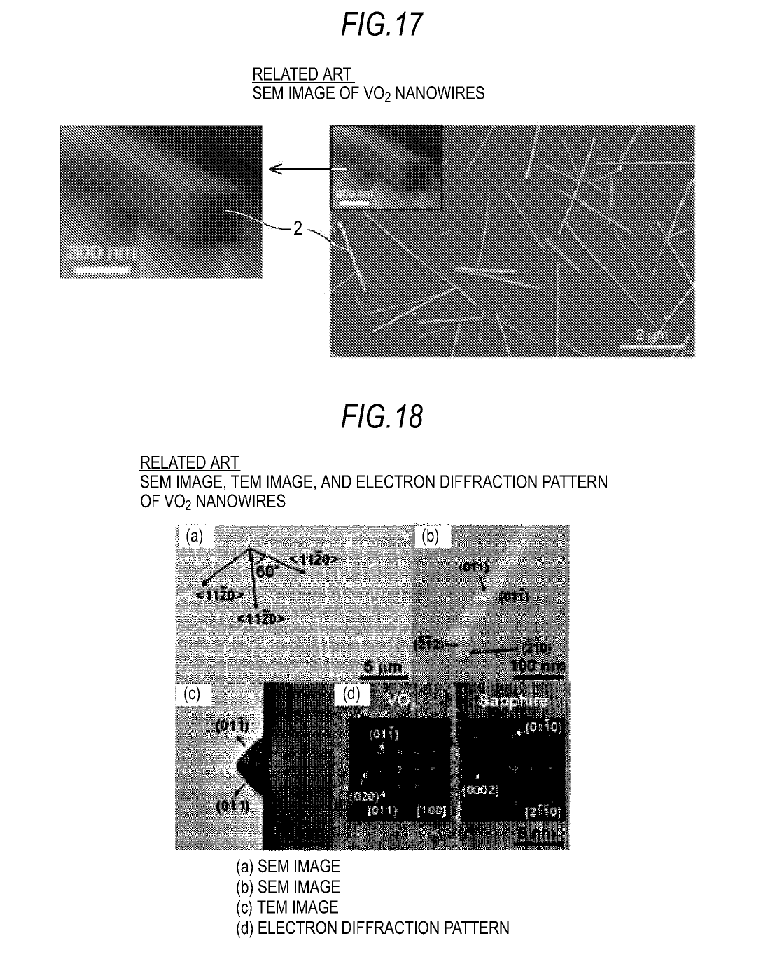

There have been no reports of VO₂ nanowire synthesis using a metal catalyst. As shown in FIG. 17 and FIG. 18, VO₂ nanowires have been synthesized on a substrate by being scattered all over the substrate in a random fashion without any control over the diameter, length, and growth position of the nanowires. There are difficulties directly using such nanowires in device applications, and such difficulties have presented a serious obstacle in device development.

The inventor of the present invention attempted to synthesize VO₂ nanowires using a gold catalyst, and has succeeded, for the first time, to synthesize VO₂ nanowires grown in the [110] direction. The growth of VO₂ nanowires with a gold catalyst using a VLS crystal growth method has made it possible to control the diameter, length, and growth position of the VO₂ nanowires.

The diameter of the VO₂ nanowires formed by the VLS crystal growth method can be controlled by the size of the metal catalyst used. Thus, by using catalysts, such as nanoparticles, having a uniform dot diameter, VO₂ nanowires of a uniform diameter can be formed, and VO₂ nanowires suitable for the development of various devices can be provided.

### <Growth of VO₂ Nanowires>

Vanadium dioxide (VO₂) nanowires of an embodiment of the present invention are long thin wires grown in the [110] direction, and undergo a metal-insulator phase transition. The high-temperature phase above the phase transition temperature is a metallic phase in which the nanowires have a tetragonal crystalline structure. The low-temperature phase below the phase transition temperature is an insulator phase in which the nanowires have a monoclinic crystalline structure. The optical properties of the VO₂ nanowires are such that, in the high-temperature phase, the VO₂ nanowires develop color as a result of reduced visible light transmittance, whereas the VO₂ nanowires are nearly transparent in the low-temperature phase. VO₂ nanowires doped with Fe, Co, Ni, Mo, Nb, or W have a lower phase transition temperature than undoped VO₂ nanowires.

The VO₂ nanowires can be formed on the TiO₂ surface of preferably, for example, a TiO₂ substrate, a Si substrate that has TiO₂ formed on a surface (TiO₂/Si substrate), and a Ti substrate that has TiO₂ formed on a surface (TiO₂/Ti substrate), using a heat vapor deposition method or a laser vapor deposition method (pulsed laser deposition method). The following descriptions will be given through the case where the VO₂ nanowires are grown on a TiO₂ substrate.

The pulsed laser deposition (PLD) method is a method in which a target is irradiated with a pulsed laser in a vacuum chamber, and the fragments (such as atoms, molecules, ions, and clusters) released as a result of formation of a target plasma are deposited on a substrate. The substance produced by the formation of a target plasma is called a plume.

Metal nanoparticles or nanodots are formed on the TiO₂ substrate and used as growth catalysts. By controlling the positions of the nanocatalysts, the positions of the initial crystal nuclei of VO₂ can be controlled, and the nanowires can have the same diameter as the nanocatalysts. Further, by extending the wires in the growth direction that lies on the most stable plane ({110} planes), autonomous thickening of the wires can be prevented.

The present invention found the growth catalyst, growth conditions, and substrate conditions suitable for the growth of VO₂ single crystalline nanowires using a catalyst. Noble metal nanoparticles or nanodots such as Au, Pt, Ag, Pd, and Ru act as growth catalysts for the growth of the VO₂ single crystalline nanowires. Au nanoparticles are particularly preferable. Nanoparticles are more controllable than nanodots in terms of size, and are therefore more suitable for the control of nanowire diameter. The growth of the VO₂ single crystalline nanowires using a noble metal nanocatalyst such as Au proceeds under a reduced pressure of 10 Pa to 1,000 Pa in an atmosphere of oxygen, inert gas, or a mixed gas of these at temperatures of 400° C. or more and 1,200° C. or less. The VO₂ single crystalline nanowires grow in the [110] direction, and unlike the autonomous growth (most stable growth) in the [100] direction, the wire diameter can be controlled according to the size of the nanocatalyst.

Any substrate can be used for the growth of the VO₂ nanowires as long as its lattice mismatch rate (lattice mismatch; defined by 100×(A−B)/A (%), where A is the lattice constant of the substrate, and B is the lattice constant of the tetragonal VO₂) for the tetragonal VO₂ is 100 or less.

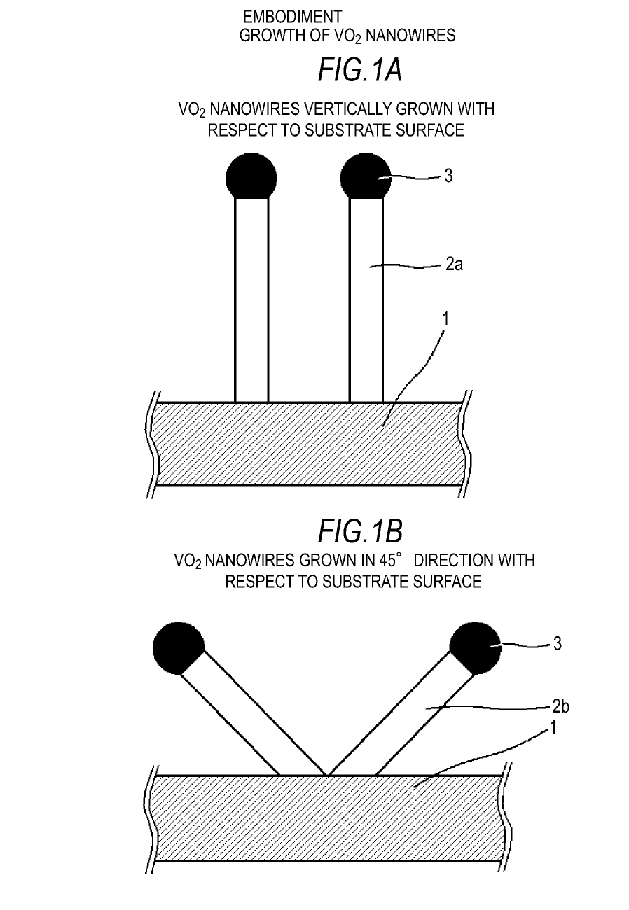

A rutile-type TiO₂ substrate, with the low lattice mismatch rate of 0.87% for the tetragonal VO₂, is particularly preferable as the substrate. As illustrated in FIG. 1B, VO₂ single crystalline nanowires formed on the (100) plane of a rutile-type TiO₂ substrate grow along the [110] direction with a 45° angle with respect to the substrate surface. Further, VO₂ single crystalline nanowires formed on the (110) plane of a rutile-type TiO₂ substrate grow along the [110] direction, perpendicular to the substrate surface.

FIGS. 1A and 1B are cross sectional views (schematic views) explaining growth of the VO₂ nanowires according to an embodiment of the present invention. FIG. 1A illustrates VO₂ nanowires grown in a direction perpendicular to the substrate surface. FIG. 1B illustrates VO₂ nanowires grown in a 45° direction with respect to the substrate surface.

As illustrated in FIG. 1A, a rutile-type TiO₂ substrate is used as a substrate 1, and a catalyst (metal catalyst) 3 is formed on the (110) plane of the substrate 1 to form the VO₂ nanowires in the manner described above. As a result, VO₂ nanowires 2a are formed that grow along the [110] direction, perpendicular to the surface of the substrate 1.

As illustrated in FIG. 1B, a rutile-type TiO₂ substrate is used as a substrate 1, and a catalyst (metal catalyst) 3 is formed on the (100) plane of the substrate (1) to form the VO₂ nanowires in the manner described above. As a result, VO₂ nanowires 2b are formed that grow along the [110] direction with a 45° angle with respect to the surface of the substrate 1.

In an embodiment of the present invention, because the VO₂ nanowires are grown bottom-up with the growth catalyst (metal catalyst) 3 using a VLS growth method, the VO₂ nanowires have the catalyst 3 at the apical portions with respect to the growth direction.

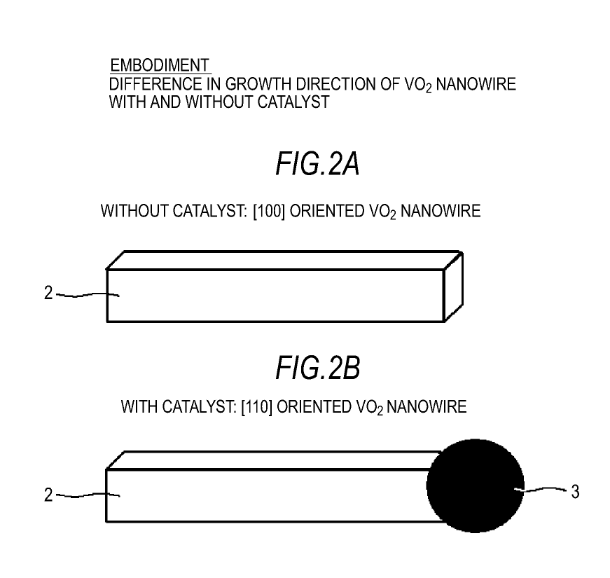

FIGS. 2A and 2B are perspective views explaining the difference in the growth direction of VO₂ nanowires with and without the catalyst, according to an embodiment of the present invention. FIG. 2A illustrates VO₂ nanowires 2 grown long and thin along the [100] direction without the catalyst. FIG. 2B illustrates VO₂ nanowires 2 grown long and thin along the [110] direction with the catalyst.

As illustrated in FIG. 2A, it is known that, without the catalyst 3, the VO₂ nanowires 2 generally grow in the [100] direction, and no other mechanism of growth has been reported. In the formation of the VO₂ nanowires 2 using, for example, gold nanodots as the catalyst 3, the VO₂ nanowires 2 are formed that grow along the [110] direction, as illustrated in FIG. 2B. There have been no reports that use a metal catalyst, for example, a gold nanodot catalyst, for the synthesis of VO₂ nanowires. It is believed that the formation of the VO₂ nanowires involves different growth modes depending on the presence or absence of a metal catalyst, as described below.

### (Crystalline Structure and Crystalline Growth of VO₂)

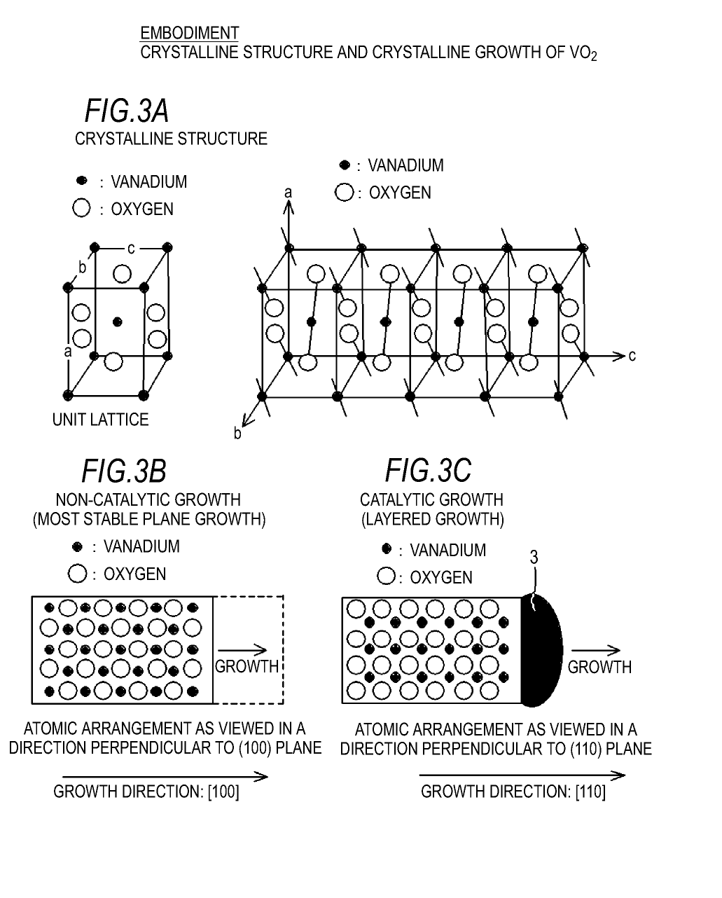

FIGS. 3A to 3C are perspective views and atomic arrangement views explaining the crystalline structure and the crystalline growth of VO₂ according to an embodiment of the present invention. FIG. 3A is a crystalline structure diagram representing a unit lattice and an arrangement along the direction of axis c. FIG. 3B is an atomic arrangement view explaining the most stable plane growth (the growth direction is the [100] direction) in the growth (non-catalytic growth) of the VO₂ nanowires without a metal catalyst, as viewed from a direction perpendicular to the (100) plane. FIG. 3C is an atomic arrangement view explaining the layered growth (the growth direction is the [110] direction) in the growth (catalytic growth) of the VO₂ nanowires with a metal catalyst, as viewed from a direction perpendicular to the (110) plane.

In the method of related art in which the VO₂ nanowires are formed without a metal catalyst, the crystalline growth in the [100] direction perpendicular to the plane in which the V and O elements necessarily occur is considered to be the most stable plane growth, as illustrated in FIG. 3B. In contrast, in the method of an embodiment of the present invention in which the VO₂ nanowires are formed with a metal catalyst, it is considered that the layer-by-layer growth in which the V-atom layer and the O-atom layer are alternately formed by the catalytic activity of the metal catalyst on crystalline growth as illustrated in FIG. 3C is the stable mode of crystalline growth that drives the VO₂ nanowires to grow in the [110] direction.

The following is a brief overview of an apparatus used for the formation of the VO₂ nanowires on a substrate.

### <VO₂ Nanowire Fabrication Apparatus>

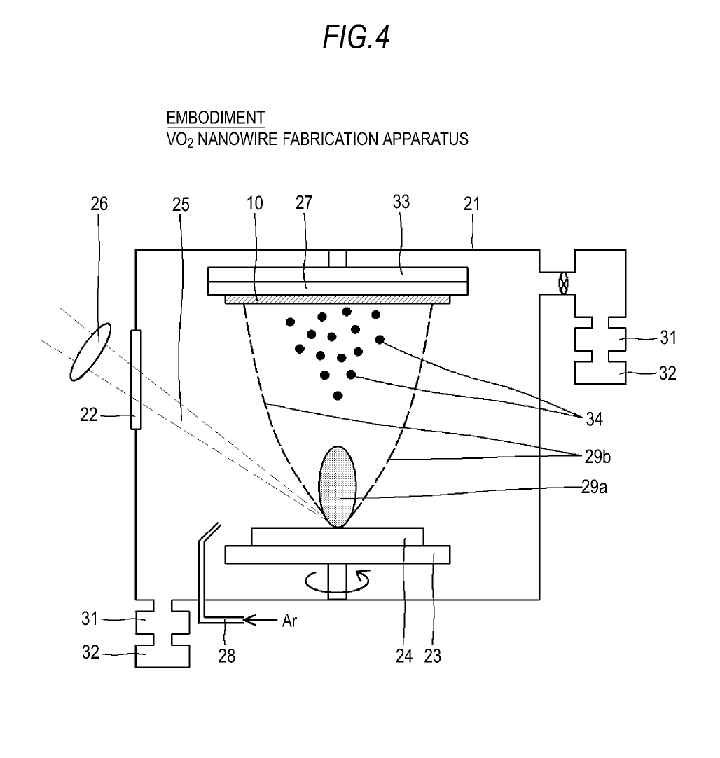

FIG. 4 is a diagram explaining a schematic structure of a VO₂ nanowire fabrication apparatus according to an embodiment of the present invention.

As illustrated in FIG. 4, in a vacuum chamber (chamber) 21, a target (for example, vanadium dioxide) 24 is held on a target support 23 on the opposite side of a substrate 10 held on a substrate support 27. The vacuum chamber 21 is also provided with a gas inlet 28 through which atmosphere gas is introduced.

The vacuum chamber 21 is controlled so that it is evacuated to a high vacuum with an oil-sealed rotary pump 31 and a turbo-molecular pump 32, and that the atmosphere gas introduced through the gas inlet 28 is maintained at a constant pressure. The atmosphere gas is, for example, a noble gas such as Ar, He, Ne, Kr, and Xe, or oxidizing gas such as oxygen. The atmosphere gas may be a mixed gas of these. During the formation of the VO₂ nanowires, inside the vacuum chamber 21 is maintained at a pressure of 10 Pa or more and 1,000 Pa or less.

During the formation of the VO₂ nanowires, the substrate 10 is heated to 400° C. or more and 1,200° C. or less, preferably to 730° C. or more and 1,200° C. or less.

Aside from vanadium dioxide, other oxides may be used as the target 24, or the target 24 may be a vanadium metal, or an alloy or an organic complex compound that includes vanadium as the base element.

The substrate 10 preferably has a crystal plane with a crystal lattice mismatch rate of 10% or less for the vanadium dioxide. For example, the substrate 10 may be a TiO₂ substrate, a Si substrate that has TiO₂ formed on a surface (TiO₂/Si substrate), and a Ti substrate that has TiO₂ formed on a surface (TiO₂/Ti substrate). The VO₂ nanowires are formed on the tetragonal TiO₂ surface of such substrates. The TiO₂ surface is a (100) plane or a (110) plane.

Nanoparticles or nanodots formed of any one of transition metal atoms selected from Au, Pt, Ag, Pd, Ru, Fe, Ni, and Cr are formed as the growth catalyst of VLS crystalline growth on the surface used to form the VO₂ nanowires. The nanoparticles or nanodots can be formed by vapor phase methods such as a CVD method, a laser method, and sputtering; liquid phase methods such as spraying, an alkoxide method, and a reverse-micelle method; and a wet or dry pulverizing method.

Because the VO₂ nanowires are formed bottom-up only in places where the growth catalysts are formed, the diameter of the VO₂ nanowires is controlled by the diameter of the growth catalysts. Thus, when the diameter of the growth catalysts is 2 nm or more and 1 μm or less, VO₂ nanowires of a size substantially corresponding to such diameters can be formed. Further, the positions and regions of the VO₂ nanowires can be controlled by forming the growth catalysts only in the places and regions of the substrate 10 where the VO₂ nanowires are to be formed, using an etching method, a shadow-mask vapor deposition, or a lift-off method.

A laser beam from a pulsed laser light source, for example, an ArF excimer laser is condensed by a lens 26 into the vacuum chamber 21 through a transparent window 22. A laser beam 25 irradiates the target 24, and the VO₂ nanowires are formed on the surface of the substrate 10 according to a pulsed laser deposition method.

The vacuum chamber 21 may be provided with an electron gun and a screen, and the electron beam from the electron gun may be incident on the surface of the substrate 10 so that the reflected electron beam diffraction image produced by the growing VO₂ nanowires on the surface of the substrate 10 can be observed on the screen.

For the formation of the VO₂ nanowires using a pulsed laser deposition (PLD) method, atmosphere gas is introduced into the vacuum chamber 21 with a pressure of 10 Pa or more and 1,000 Pa or less. In this pressure range, a low-density plume 29b (indicated by dotted line) that emanates from a high-density plume 29a (indicated by solid line) prevents a cluster (fragments) 34 (such as atoms, molecules, and ions) released by the formation of a plasma from the target 24 from reaching the surface of the substrate 10. Thus, the cluster 34 deposits on the surfaces of the growth catalysts formed on the surface of the substrate 10, and the VO₂ nanowires are formed bottom-up.

The growth rate of the VO₂ nanowires formed by the PLD method is determined by such factors as the temperature of the substrate 10, the distance between the substrate 10 and the target 24, the type of atmosphere gas and gas pressure, the wavelength of the laser used, irradiation energy (density), pulse oscillation frequency, pulse width, and irradiation time.

The VO₂ nanowires grow long and thin along the [110] direction. The VO₂ nanowires grow in a 90° direction with respect to the surface of the substrate 10 when formed on the crystal plane (110) of TiO₂ used as the substrate 10, and in a 45° direction with respect to the surface of the substrate 10 when formed on the crystal plane (100) of the substrate TiO₂.

Because the VO₂ nanowires are formed bottom-up with respect to the growth catalyst, the as-formed VO₂ nanowires have the growth catalyst at the top (apical portion). The growth catalyst at the top of the VO₂ nanowires can be removed by etching. Further, the as-formed VO₂ nanowires may be doped with Fe, Co, Ni, Mo, Nb, or W to provide a phase transition temperature different from that of undoped VO₂ nanowires.

The VO₂ nanowires formed with the apparatus illustrated in FIG. 4 can be suitably used for various types of nanowire devices, including an electronic device that detects changes in electrical resistance in response to heat, electric field, infrared rays, visible light, electromagnetic waves, pressure, or vibration, or changes in the transmittance or reflectance of infrared rays or visible light, an electronic device that includes an electrode realized by the vanadium dioxide nanowires, and a catalytic device in which the vanadium dioxide nanowires are used as a photocatalyst or an alcoholysis catalyst.

Examples of such electronic devices include a temperature-detecting sensor device, an acceleration-detecting sensor device, a gas-detecting sensor device, an electromagnetic wave-detecting sensor device, a photo-detecting sensor device, a pressure-detecting sensor device, a field-effect transistor device, a nonvolatile memory device, a photoelectric conversion device, an optical switching device, a heat modulation device, a light modulation device, a switching circuit device, a phototransistor device, and an optical memory device. Examples of the electrode include an electrical double layer capacitor electrode, an electrochemical capacitor electrode, and an electrode for alkali-ion secondary batteries.

### <Basic Structure of Nanowire Device Using VO₂ Nanowires>

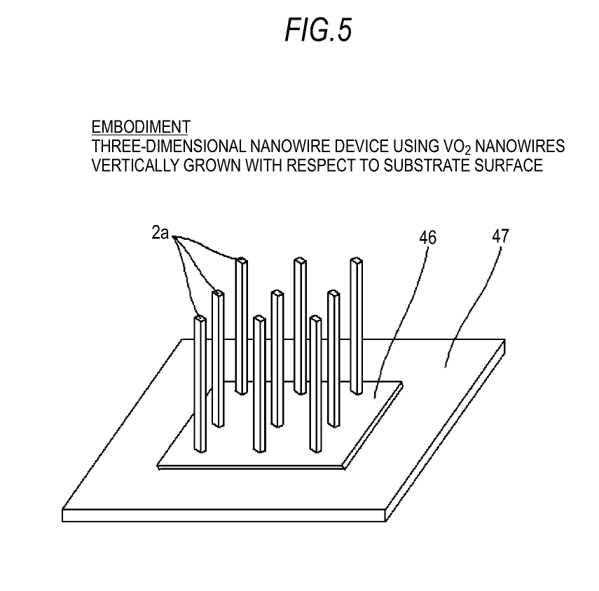

FIG. 5 is a perspective view explaining a basic structure of a three-dimensional nanowire device that uses VO₂ nanowires vertically grown on a substrate surface, according to an embodiment of the present invention.

As illustrated in FIG. 5, the basic structure of the three-dimensional nanowire device includes VO₂ nanowires 2a formed on a surface of an electrode 46 formed on a substrate 47, and that are vertically grown with respect to a substrate surface. The substrate 47 is, for example, a Si substrate or a Ti substrate. The electrode 46 formed on the surface of the substrate 47 is tetragonal TiO₂, which is doped with 0.05% to 1% Nb to give TiO₂:Nb having metallic properties. The Nb doping of TiO₂ is not required when the nanowire device does not require an electrode as in catalytic devices. In this case, tetragonal TiO₂ may be used as the substrate 47, and the VO₂ nanowires 2a may be formed thereon, without using the electrode 46.

The following describes a field-effect transistor (FET) as an example of the nanowire device.

### Field-Effect Transistor (FET)

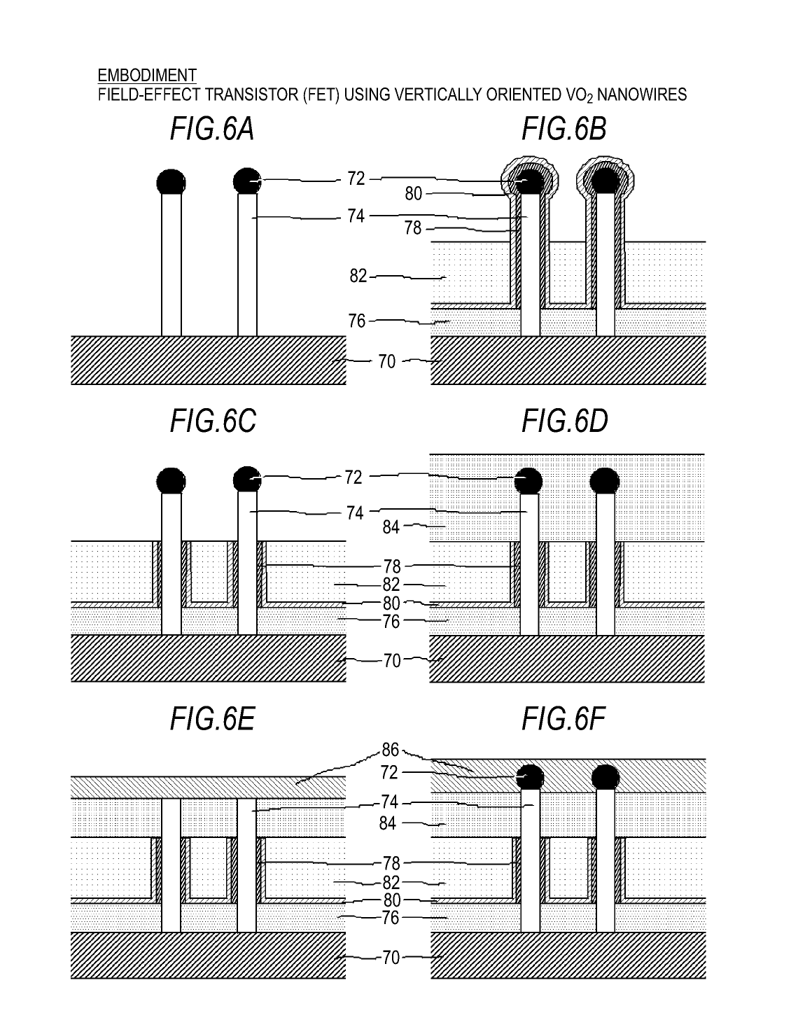

FIGS. 6A to 6F are cross sectional views schematically explaining the fabrication steps of a field-effect transistor (FET) that uses vertically oriented VO₂ nanowires, according to an embodiment of the present invention. For simplicity, FIGS. 6A to 6F illustrate only a portion of the field-effect transistor (FET).

The FET illustrated in FIGS. 6A to 6F is a gate-around transistor of a structure in which portions of the vertically extending VO₂ nanowires are surrounded by a gate electrode.

As illustrated in FIG. 6A, vertically oriented VO₂ nanowires 74 (used as a channel) are formed on a TiO₂ substrate 70 (Nb-doped substrate used as a drain electrode; corresponding to the electrode 46 illustrated in FIG. 5) using a VLS growth method. A metal catalyst 72 is present at the apical portions of the VO₂ nanowires 74.

As illustrated in FIG. 6B, a first insulating layer 76 is formed on the substrate 70, covering the whole surface of the substrate 70 and in contact with portions of the nanowires 74. The first insulating layer 76 is provided to electrically separate the substrate 70 (drain electrode) from a first conductive layer 80 (gate electrode). Then, a second insulating layer 78 (gate insulating film) is formed so as to cover the whole of the nanowires 74, followed by formation of the first conductive layer 80 (gate electrode) and a protective insulating layer 82, in this order.

Thereafter, as illustrated in FIG. 6C, portions of the second insulating layer 78 and the first conductive layer 80 above the protective insulating layer 82 are removed by etching, and, as illustrated in FIG. 6D, a third insulating layer 84 is formed over the catalysts 72 and the nanowires 74 exposed above the protective insulating layer 82.

Then, as illustrated in FIG. 6E, the third insulating layer 84 in the structure of FIG. 6D is polished to remove the catalyst 72 and expose a cross section of the nanowires 74, and a second conductive layer 86 (source electrode) is formed. Alternatively, as illustrated in FIG. 6F, the second conductive layer 86 (source electrode) is formed after the third insulating layer 84 in the structure of FIG. 6D is removed by etching to expose the catalysts 72.

The nanowires 74 may serve as a parallel channel to form a single FET, or the FET may be of a multiple channel structure in which the source and drain electrodes formed in rows and columns, respectively, are used to control operation in units of a predetermined number of the nanowires 74 respectively formed on the columns of the drain electrodes.

The following describes an electrochemical (redox) capacitor as another example of the nanowire device. The redox capacitor is a capacitor that uses pseudocapacitance to increase the capacitance of the electrical double layer capacitor, and that uses the oxidation and reduction of the electrode material, the charge and discharge of the electrical double layer, and the desorption and adsorption of ions on the electrode surface for the storage and release of electrical energy.

### (Electrochemical (Redox) Capacitor)

Vanadium dioxide is usable as electrode material of redox capacitors that involve electrochemical reactions. Generally, the vanadium ions in vanadium dioxide change valency from the tetravalent V⁴⁺ to the trivalent V³⁺ or the pentavalent V⁵⁺ by the electrochemical donation and acceptance of electrons. The capacitance can be increased by utilizing such electrochemical reactions for the redox capacitor. The redox capacitor is preferably a structure with a large surface area. Previous attempts to provide redox capacitors commonly used powders or nanoparticles immobilized with a thin film or an adhesive. The nanowire array not only increases surface area by high density, but improves the power collection to the collectors because of the direct single crystal formation from the collectors.

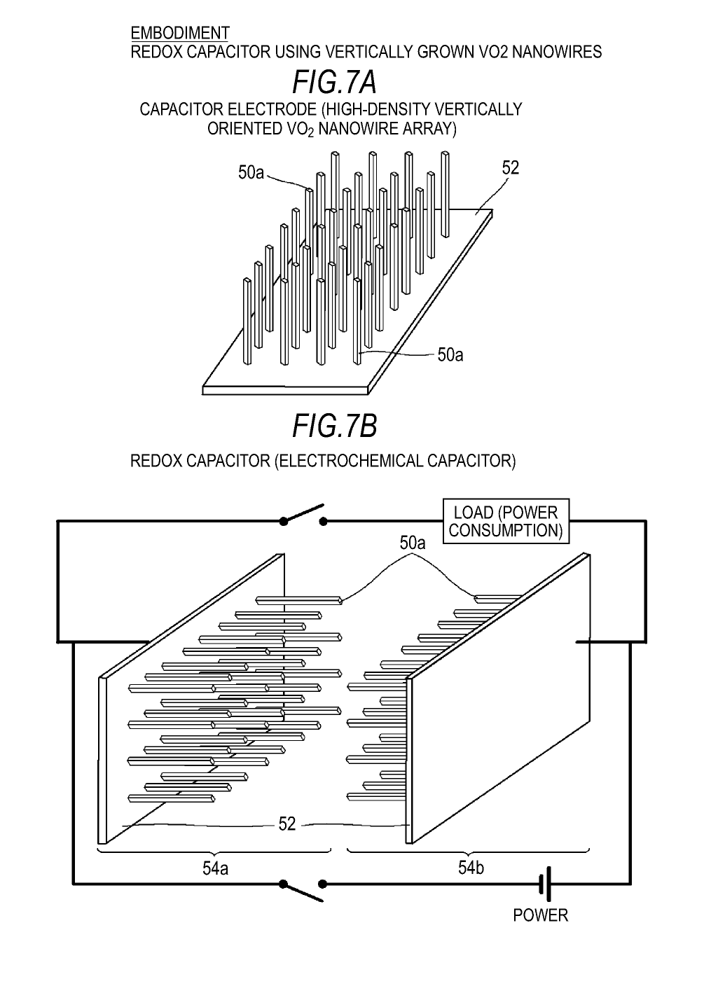

FIGS. 7A and 7B are perspective views explaining a redox capacitor that uses vertically grown VO₂ nanowires, according to an embodiment of the present invention.

FIG. 7A is a perspective view illustrating a capacitor electrode that uses high density, vertically oriented VO₂ nanowires. FIG. 7B is a perspective view of a redox capacitor using the capacitor electrode.

Electrochemical (redox) capacitors using metal oxide electrodes can store charge by the faradic process involving oxidation and reduction of metallic species, in addition to the capacitance of the electrical double layer. Thus, electrochemical capacitors are capable of producing higher output than electrical double layer capacitors that use activated carbon.

As illustrated in FIGS. 7A and 7B, vertically oriented VO₂ nanowires 50a formed on a collector 52 are used as metal oxide capacitor electrodes 54a and 54b. The collector 52 is the electrode 46 illustrated in FIG. 5. An electrolyte solution is placed between the capacitor electrodes 54a and 54b to form the electrochemical (redox) capacitor.

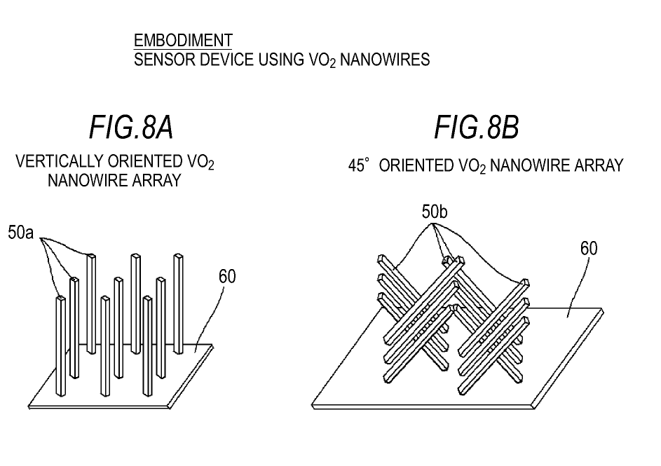

The nanodevices described above are based on the vertically oriented VO₂ nanowire array of FIG. 8A that uses vertically oriented VO₂ nanowires 50a formed on an electrode 60 or a substrate. However, the nanodevice may be based on a 45° oriented VO₂ nanowire array illustrated in FIG. 8B that uses 45° oriented VO₂ nanowires 50b formed on the electrode 60 or a substrate. The same can be said for the nanowire devices described below.

FIGS. 8A and 8B are perspective views explaining a sensor device that uses the VO₂ nanowires, according to an embodiment of the present invention. FIG. 8A is a perspective view illustrating a vertically oriented VO₂ nanowire array. FIG. 8B is a perspective view illustrating a 45° oriented VO₂ nanowire array.

A catalytic device is described below as another example of the nanowire device.

### (Catalytic Device)

The VO₂ nanowires undergo a phase transition by the energetic instability due to light, electric field, or pressure. Vanadium dioxide easily undergoes a metal-insulator transition in response to light, and is therefore very responsive to light. In the photo-induced phase transition, the instable energy can be used for chemical reaction to cause a photocatalytic reaction, instead of using it for the phase transition that brings a structural change. Further, by attaching semiconductor photocatalytic nanoparticles such as TiO₂ to the VO₂ nanowires, even higher catalytic activity can be obtained.

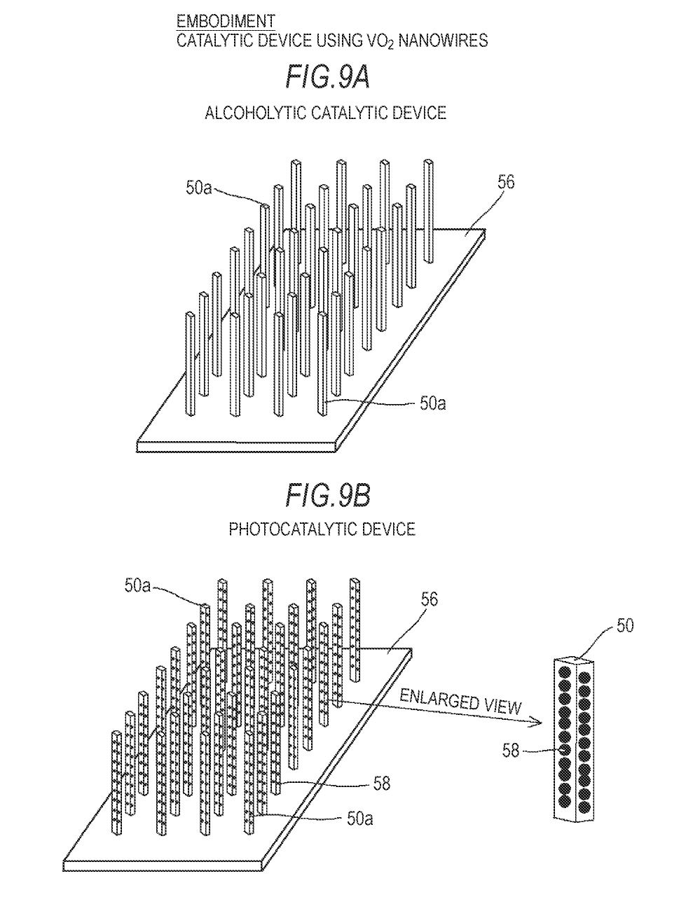

FIGS. 9A and 9B are perspective views explaining a catalytic device that uses the VO₂ nanowires, according to an embodiment of the present invention. FIG. 9A is a perspective view illustrating an alcoholytic catalytic device. FIG. 9B is a perspective view illustrating a photocatalytic device.

As illustrated in FIG. 9A, in the alcoholytic catalytic device, large numbers of vertically oriented VO₂ nanowires 50a of vanadium dioxide having alcoholytic catalytic activity are formed on a substrate 56 to increase the surface area available for the alcoholytic reaction.

In the photocatalytic device illustrated in FIG. 9B, large numbers of vertically oriented VO₂ nanowires 50a of vanadium dioxide having photocatalytic activity are formed on a substrate 56, and semiconductor photocatalytic nanoparticles TiO₂ having photocatalytic activity are additionally attached as photocatalyst particles 58 to the surfaces of the nanowires 50a, in order to provide even higher catalytic activity and to increase the surface area available for the photocatalytic reaction.

Though not illustrated, the VO₂ nanowires are also applicable to various other nanowire devices.

Vanadium dioxide undergoes a metal-insulator phase transition in response to light (electromagnetic waves) or pressure, and changes its state between a metallic electrical conductor, an insulator, and a semiconductive electrical conductor. Thus, light (electromagnetic waves) can be detected (received) by reading such changes in electrical conductance. The VO₂ nanowires can therefore be used as an optical sensor for visible light, an RF sensor for high-frequency radio waves, a pressure sensor for pressure, or an angular velocity (gyro) sensor that takes advantage of the bending caused by vertical and horizontal swings. For the application of the VO₂ nanowires as an optical sensor, for example, the insulating layer and the conductive layer disposed in the light path to the VO₂ nanowires in the structure illustrated in FIGS. 6A to 6F are made of transparent material, without providing the gate electrode.

Examples concerning formation of the VO₂ nanowires are described below.

### Examples

### Formation of Gold Catalyst (Growth Catalyst)

A rutile-type TiO₂ substrate having a good lattice match with tetragonal VO₂ was used as a substrate for the VO₂ nanowires. In order to form dot catalysts on a substrate surface, a ultrathin gold film having a thickness of about 2 nm was formed on a surface of the substrate using a vacuum vapor deposition method. The substrate was heated to about 700° C. to aggregate the ultrathin gold film and form gold dot catalysts measuring about 50 nm to 100 nm.

### <Formation of VO₂ Nanowires by PLD>

The VO₂ nanowires were formed by PLD, for example, under the following conditions. That is, a vanadium oxide such as V₂O₅, V₂O₃, and V₂O₄, or a compacted powder calcined pellet using a vanadium metal alone (V₂O₅ pellet in this example) was used as the target, and an excimer laser having a wavelength of 248 nm was used, and Au-catalyzed growth of the VO₂ nanowires was successfully conducted at a repetition frequency of 1 Hz to 7 Hz, at a substrate temperature of 650° C. under an argon atmosphere of 0.5 Torr to 10 Torr. The growth temperature of the VO₂ nanowires was set to 650° C. in order that the fragments generated by the irradiation of the target with the laser adhere to the gold catalysts and melt into the gold catalysts with improved uptake, and readily migrate within the gold catalysts. Further, this temperature was selected to suppress self growth in areas where there is no catalyst. Immediately after the formation, the VO₂ nanowires have a high-temperature-phase tetragonal structure, but changes to a low-temperature-phase monoclinic structure in a reduced temperature state of the substrate at room temperature.

### <Formation of VO₂ Nanowires in Relation to Temperature and Pressure>

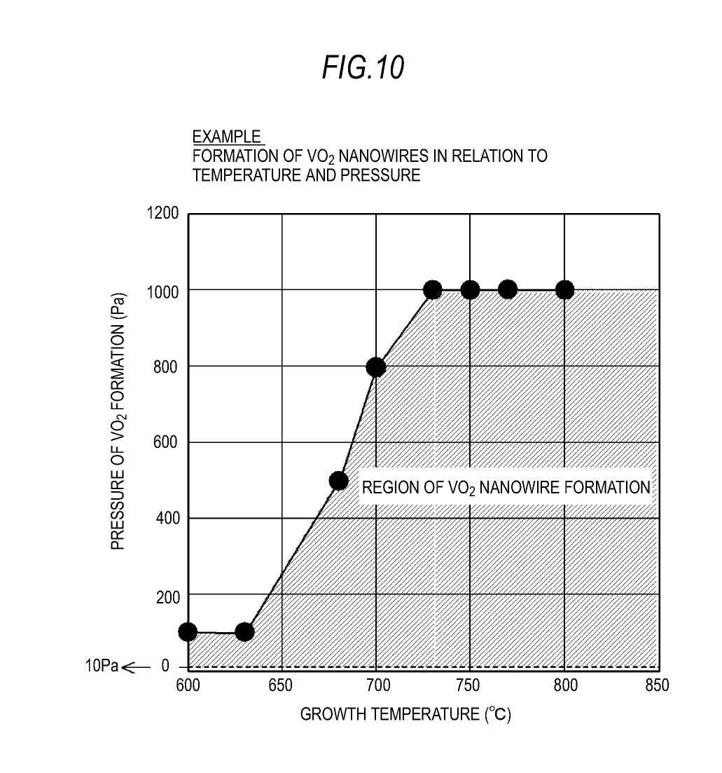

FIG. 10 is a graph representing VO₂ nanowire formation in relation to temperature and pressure, according to Example of the present invention. In FIG. 10, the horizontal axis represents the growth temperature (substrate temperature, in Celsius) of the VO₂ nanowires. The vertical axis represents the pressure (Pa) of VO₂ nanowire formation.

The shaded region in FIG. 10 represents a region of VO₂ nanowire formation, where the pressure is 10 Pa or more and 1,000 Pa or less. Formation of the VO₂ nanowires above 1,000 Pa is possible at temperatures of about 730° C. and greater; however, the growth rate will be lower than when the pressure is 1,000 Pa, because the mean free path of the fragments generated by the irradiation of the target with the laser becomes small.

For the efficient formation of the purest possible VO₂ nanowires that contain no impurities, it is preferable that the growth of VO₂ nanowires occur in a region where the temperature is about 730° C. or more, and the pressure is 10 Pa or more and 1,000 Pa or less.

The following describes the relationship between the growth direction of the VO₂ nanowires and substrate surface.

### (Formation of VO₂ Nanowires on TiO₂ (100) Plane)

Gold catalysts similar to the one described above were formed on the (100) plane of rutile-type TiO₂, and the VO₂ nanowires were grown with the gold catalysts using a vanadium oxide such as V₂O₅, V₂O₃, and V₂O₄, or a compacted powder calcined pellet that uses a vanadium metal alone (V₂O₅ pellet in this example) as a target and an excimer laser having a wavelength of 248 nm at a repetition frequency of 1 Hz to 7 Hz, at a substrate temperature of 650° C. and under an argon atmosphere of 0.5 Torr to 10 Torr.

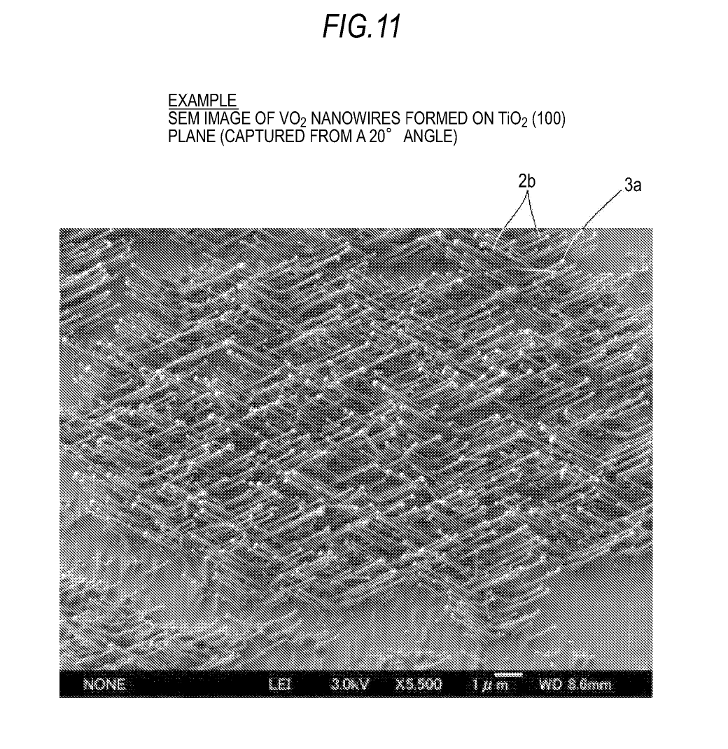

FIG. 11 is a SEM image of the VO₂ nanowires formed on the TiO₂ (100) plane according to Example of the present invention (the image was captured with a substrate tilt angle of 20°).

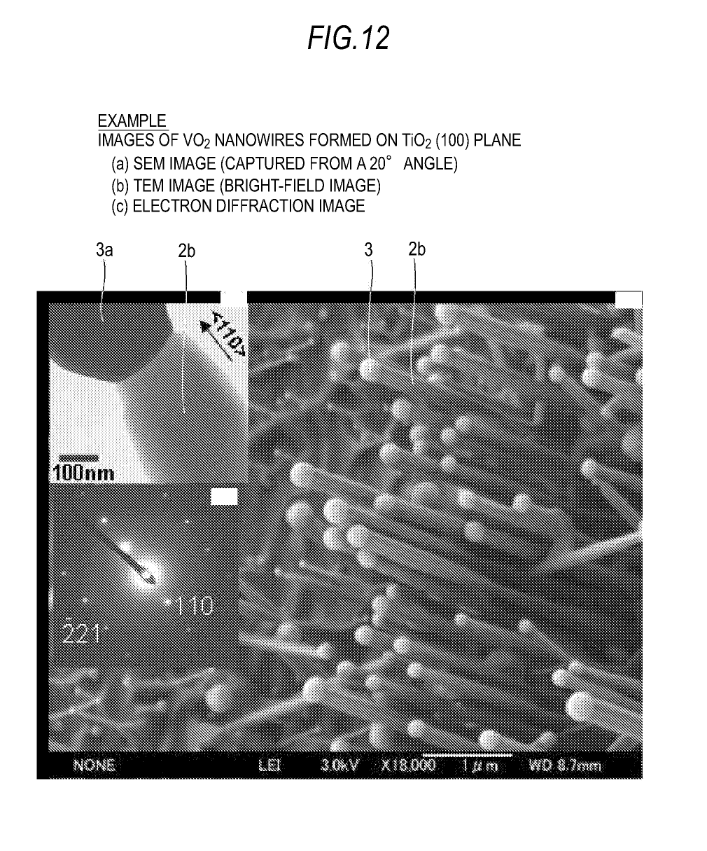

FIG. 12 shows images of the VO₂ nanowires formed on the TiO₂ (100) plane according to Example of the present invention, in which (a) is a SEM image (the images were captured with a substrate tilt angle of 20°), (b) is a TEM image, and (c) is an electron diffraction image.

It can be seen in FIG. 11 and FIG. 12 that VO₂ nanowires 2b of substantially the same diameter and length are grown in a 45° direction with respect to the rutile-type TiO₂ (100) plane, and that the VO₂ nanowires 2b have gold catalysts 3a at the apical portions. Typical dimensions of the VO₂ nanowires 2b shown in FIG. 11 are 150 nm in diameter, and 2.5 μm in length. TEM analysis and Raman spectroscopy confirmed that the nanowires had a VO₂ structure. As shown in (b) in FIG. 12, the result of TEM analysis revealed that the VO₂ nanowires formed by the VLS growth method using the gold catalysts were formed along the [110] direction.

The VO₂ nanowire growth along the [110] direction is in accordance with the 45° epitaxial growth of the VO₂ nanowires on the TiO₂ (100) plane shown in the SEM image of FIG. 11. These results demonstrate the previously unreported oriented growth along the [110] direction. In the methods of related art not using a metal catalyst, the growth of the VO₂ nanowires is typically along the [100] direction. This is due to the most stable structure of VO₂, as described above. As will be described later in Comparative Example, the VO₂ nanowires indeed grow along the [100] direction in methods that do not use a gold catalyst, which is consistent with the reports in the related art. Thus, it can be said that the VO₂ nanowire growth along the [110] direction is due to the effect of the gold catalyst.

Experiment was conducted using a TiO₂ (110) substrate whose surface was inclined 45° with respect to the TiO₂ (100) substrate plane.

### (Formation of VO₂ Nanowires on TiO₂ (110) Plane)

Gold catalysts similar to the one described above were formed on the (110) plane of rutile-type TiO₂, and the VO₂ nanowires were grown with the gold catalysts using a vanadium oxide such as V₂O₅, V₂O₃, and V₂O₄, or a compacted powder calcined pellet that uses a vanadium metal alone (V₂O₅ pellet in this example) as a target, and an excimer laser having a wavelength of 248 nm at a repetition frequency of 1 Hz to 7 Hz, at a substrate temperature of 650° C. under an argon atmosphere of 0.5 Torr to 10 Torr.

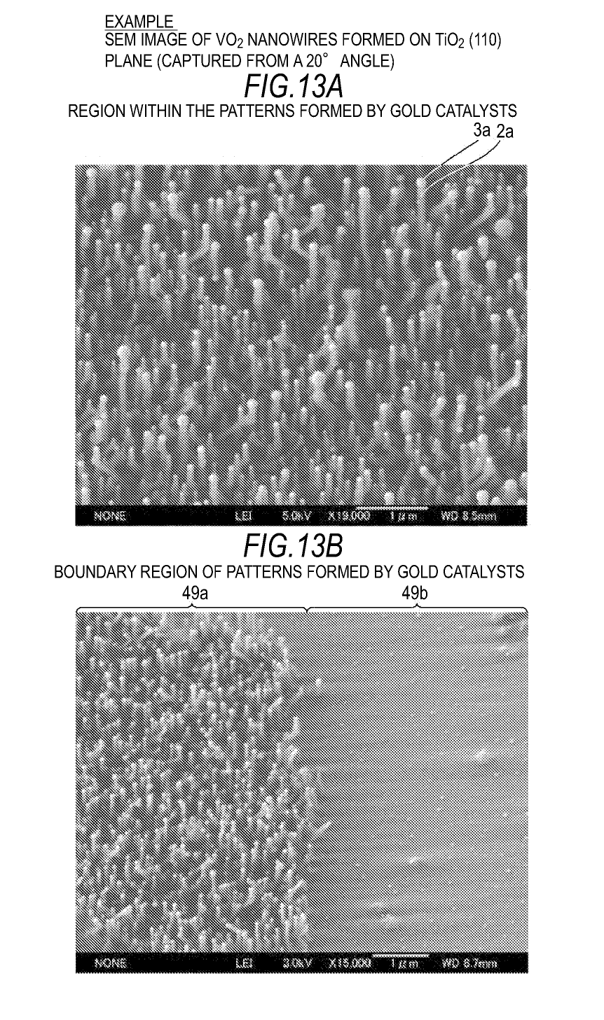

FIGS. 13A and 13B are SEM images of the VO₂ nanowires formed on the TiO₂ (110) plane according to Example of the present invention (the images were captured with a substrate tilt angle of 20°). FIG. 13A is a SEM image showing a region within the patterns formed by the gold catalysts. FIG. 13B is a SEM image in a boundary region of the patterns formed by the gold catalysts.

It can be seen in FIG. 13A that VO₂ nanowires 2a of substantially the same diameter and length are vertically grown on the rutile-type TiO₂ (110) plane, and that the VO₂ nanowires 2a have gold catalysts 3a at the apical portions. Typical dimensions of the VO₂ nanowires 2a shown in FIGS. 13A and 13B are 50 nm in diameter, and 500 nm in length.

As shown in FIG. 13B, the VO₂ nanowires 2a were formed only in a region 49a that had the patterns of the gold catalysts, and no VO₂ nanowires 2a were formed in a region 49b in which patterns of the gold catalysts were not present.

As a comparative example, VO₂ nanowires were formed without using the gold catalyst.

### Comparative Example

VO₂ nanowires were grown on a Si substrate (without the gold catalyst) using a V₂O₅ pellet as a target and an excimer laser having a wavelength of 248 nm at a repetition frequency of 1 Hz to 7 Hz, at a substrate temperature of 650° C. and an argon atmosphere of 0.5 Torr to 10 Torr. The following results were obtained from the VO₂ nanowires so obtained.

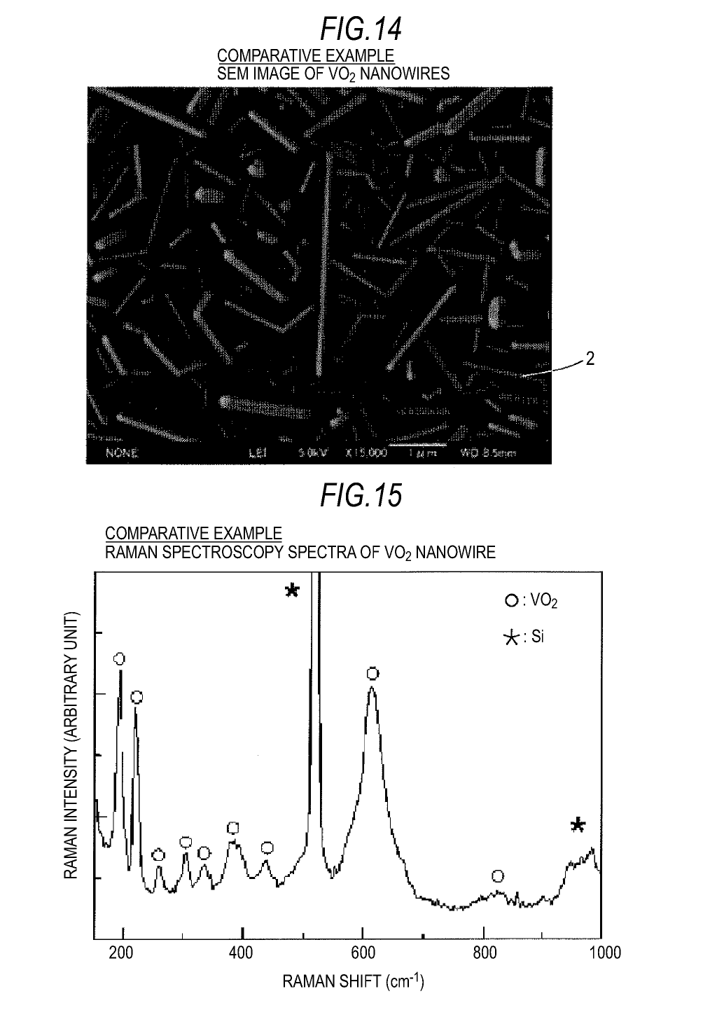

FIG. 14 is a SEM image of the VO₂ nanowires according to Comparative Example of the present invention.

As shown in FIG. 14, the VO₂ nanowires were formed parallel to the substrate, and the diameter, length, and position of the VO₂ nanowires were disordered and non-uniform.

FIG. 15 shows Raman spectroscopy spectra of the VO₂ nanowires according to Comparative Example of the present invention. In FIG. 15, the horizontal axis represents Raman shift (cm⁻¹), and the vertical axis represents Raman intensity (arbitrary unit).

As represented in FIG. 15, the Raman spectroscopy spectra show that the VO₂ nanowires are without different phases.

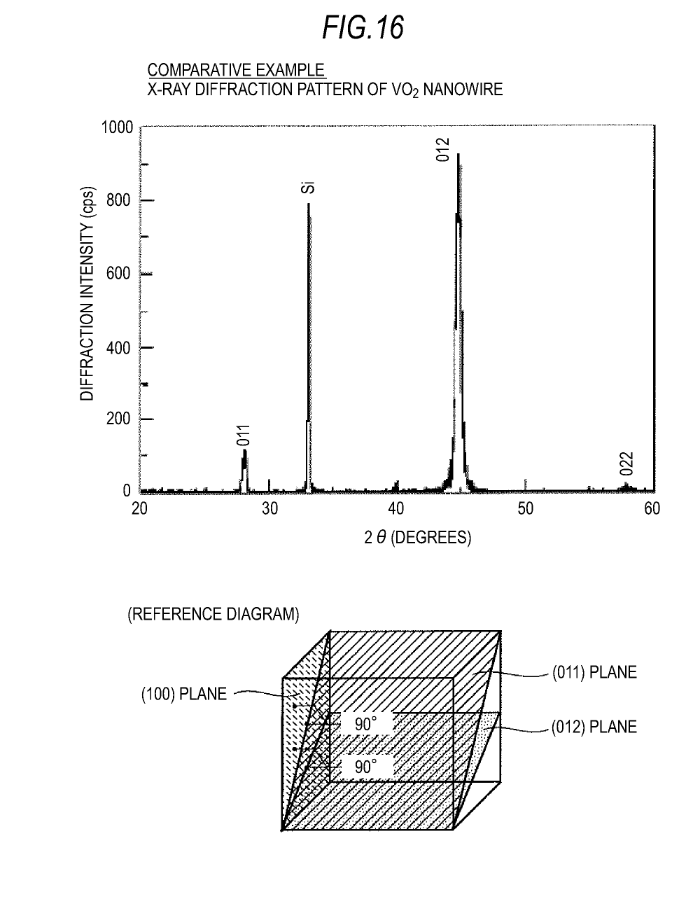

FIG. 16 shows the X-ray diffraction (XRD) pattern of the VO₂ nanowires according to Comparative Example of the present invention. In FIG. 16, the horizontal axis represents diffraction angle 2θ (degrees), and the vertical axis represents diffraction intensity (cps).

In the XRD pattern of FIG. 16, four diffraction peaks were confirmed for the (011), (012), and (022) planes of the tetragonal VO₂. Because these planes are orthogonal to the (100) plane, it can be seen that the nanowires are oriented in the [100] direction (see the reference diagram in the figure).

The VO₂ nanowires formed without the gold catalyst grow in the [100] direction because the most stable plane of the VO₂ is the {011} plane, and, in the case of nanowires, tends to lie on the side faces of the nanowires. In other words, the most stable structure is that in which the side faces of the nanowires lie on the {011} planes, and in which the wire growth direction is the [100] direction. As such, naturally grown VO₂ nanowires formed without the gold catalyst grow in the [100] direction.

As is clear from the comparison between Example and Comparative Example, the majority of the VO₂ nanowires have the axial direction inclined 90° or 45° with respect to the substrate surface, and are formed bottom-up with respect to the gold catalyst in substantially a uniform fashion in terms of diameter, length, and position.

The invention has been specifically described with respect to certain embodiments and examples. However, the invention is not limited to the foregoing embodiments and examples, and various modifications are possible based on the technical ideas of the invention.

Vanadium dioxide nanowires of the present invention can be suitably used for various types of nanowire devices.

The present application contains subject matter related to that disclosed in Japanese Priority Patent Application JP 2009-143007 filed in the Japan Patent Office on Jun. 16, 2009, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A vanadium dioxide nanowire grown long and thin along a [110] direction.

2. The vanadium dioxide nanowire according to claim 1, wherein the nanowire has a diameter of 2 nm or more and 1 μm or less.

3. A process for fabricating a vanadium dioxide nanowire,
the process comprising:
a first step of forming a transition-metal-atom growth catalyst on a substrate; and
a second step of growing a nanowire of vanadium dioxide on a surface of the substrate heated under reduced pressure in an atmosphere of any one of oxygen gas, inert gas, and a mixed gas of these.

4. The process according to claim 3, wherein the nanowire is grown long and thin along a [110] direction.

5. The process according to claim 3, wherein the substrate surface is a crystal plane having a crystal lattice mismatch rate of 10% or less for the vanadium dioxide.

6. The process according to claim 5, wherein the nanowire grows in a 90° or 45° direction with respect to the substrate surface.

7. The process according to claim 6, wherein the nanowire grows in a 90° direction with respect to the substrate surface when the substrate is tetragonal TiO₂ and when the crystal plane is (110), and grows in a 45° direction with respect to the substrate surface when the substrate is tetragonal TiO₂ and when the crystal plane is (100).

8. The process according to claim 3, wherein, in the second step, the nanowire is grown under a reduced pressure of 10 Pa or more and 1,000 Pa or less.

9. The process according to claim 3, wherein, in the second step, the substrate is heated to 400° C. or more and 1,200° C. or less.

10. The process according to claim 3, wherein, in the second step, the substrate is heated to 730° C. or more and 1,200° C. or less, and the nanowire is grown under a reduced pressure of 10 Pa or more and 1,000 Pa or less.

11. The process according to claim 3, wherein nanoparticles or nanodots are used as the growth catalyst, and wherein the transition metal atom is any one of Au, Pt, Ag, Pd, Ru, Fe, Ni, and Cr.

12. The process according to claim 3, wherein the nanowire is grown using a laser vapor deposition method or a heat vapor deposition method, using at least one of an alloy, an oxide, an organic complex compound each containing vanadium as a base element, and a vanadium metal.

13. The process according to claim 3, wherein the diameter of the growth catalyst is controlled to control the diameter of the nanowire.

14. The process according to claim 13, wherein the growth catalyst has a diameter of 10 nm or more and 1 μm or less.

15. The process according to claim 3, wherein, in the first step, the growth catalyst is formed in a desired region of the substrate using any one of an etching method, shadow-mask vapor deposition, and a lift-off method.

16. The process according to claim 3, further comprising a third step of removing the growth catalyst at an apical portion of the nanowire.

17. The process according to claim 3, wherein the nanowire includes at least one of a 3d transition metal element, a rare-earth element, Ta, and W as an addition element.

18. The process according to claim 17, wherein the addition element is contained in a content of 5% (atomic fraction) or less.

19. A nanowire device configured as any one of:
an electronic device including the vanadium dioxide nanowire of claim 1 or 2, and that detects changes in electrical resistance in response to heat, electric field, infrared rays, visible light, electromagnetic waves, pressure, or vibration, or changes in the transmittance or reflectance of infrared rays or visible light;
an electronic device that includes an electrode realized by the vanadium dioxide nanowire; and
a catalytic device in which the vanadium dioxide nanowire is used as a photocatalyst or an alcoholysis catalyst.

20. The nanowire device according to claim 19,
wherein the electronic device is any one of a temperature-detecting sensor device, an acceleration-detecting sensor device, a gas-detecting sensor device, an electromagnetic wave-detecting sensor device, a photo-detecting sensor device, a pressure-detecting sensor device, a field-effect transistor device, a nonvolatile memory device, a photoelectric conversion device, an optical switching device, a heat modulation device, a light modulation device, a switching circuit device, a phototransistor device, and an optical memory device, and
wherein the electrode is anyone of an electrical double layer capacitor electrode, an electrochemical capacitor electrode, and a positive electrode for alkali-ion secondary batteries.
